(19) United States
(12) Patent Application Publication
(10) Pub. No.: US 2024/0030156 A1
(43) Pub. Date: Jan. 25, 2024

(54) SEMICONDUCTOR DEVICE AND METHOD FOR MANUFACTURING THE SAME

(71) Applicant: INNOSCIENCE (SUZHOU) SEMICONDUCTOR CO., LTD., Suzhou City (CN)

(72) Inventor: Chang An LI, Suzhou City (CN)

(21) Appl. No.: 17/442,139

(22) PCT Filed: Aug. 11, 2021
(86) PCT No.: PCT/CN2021/112114

§ 371 Date: Sep. 23, 2021

(51) Int. Cl. H01L 23/00; H01L 23/31; H01L 29/20; H01L 29/417; H01L 29/778; H01L 29/40; H01L 29/66

(52) U.S. Cl. CPC H01L 23/562; H01L 23/3171; H01L 29/2003; H01L 29/41758; H01L 29/7786; H01L 29/401; H01L 29/66462

(57) ABSTRACT

A semiconductor device includes a first and a nitride-based semiconductor layers, a gate electrode, a dielectric layer, a first contact electrode and a passivation layer. The dielectric layer covers the gate electrode. The first contact electrode penetrates the dielectric layer to make contact with the second nitride-based semiconductor layer. The first contact electrode includes one or more enclosed discontinuities in a first discontinuity region thereof. The passivation layer is disposed above the dielectric layer and covers the first contact electrode. The passivation layer penetrates the first contact electrode in the first discontinuity region to make contact with the second nitride-based semiconductor layer.

### FIELD OF THE DISCLOSURE

The present disclosure generally relates to a nitride-based semiconductor device. More specifically, the present disclosure relates to a nitride-based semiconductor device with an embedded/buried contact electrode including one or more enclosed discontinuities

### BACKGROUND

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET). At present, there is a need to improve the yield rate for HMET devices, thereby making them suitable for mass production.

### Summary of the Disclosure

In accordance with one aspect of the present disclosure, a semiconductor device is provided. A semiconductor device includes a first nitride-based semiconductor layer, a second nitride-based semiconductor layer, a gate electrode, a dielectric layer, a first contact electrode and a passivation layer. The second nitride-based semiconductor layer is disposed on the first nitride-based semiconductor layer and has a bandgap greater than a bandgap of the first nitride-based semiconductor layer. The gate electrode is disposed above the second nitride-based semiconductor layer. The dielectric layer is disposed above the second nitride-based semiconductor layer and covers the gate electrode. The first contact electrode is disposed above the second nitride-based semiconductor layer and penetrates the dielectric layer to make contact with the second nitride-based semiconductor layer. The first contact electrode includes one or more enclosed discontinuities in a first discontinuity region thereof. The passivation layer is disposed above the dielectric layer and covers the first contact electrode. The passivation layer penetrates the first contact electrode in the first discontinuity region to make contact with the second nitride-based semiconductor layer.

In accordance with one aspect of the present disclosure, a semiconductor device is provided. A semiconductor device includes a first nitride-based semiconductor layer, a second nitride-based semiconductor layer, a gate electrode, a dielectric layer, a contact electrode, and a passivation layer. The second nitride-based semiconductor layer is disposed on the first nitride-based semiconductor layer and has a bandgap greater than a bandgap of the first nitride-based semiconductor layer. The gate electrode is disposed above the second nitride-based semiconductor layer. The dielectric layer is disposed above the second nitride-based semiconductor layer and covers the gate electrode. The contact electrode is disposed above the second nitride-based semiconductor layer and penetrates the dielectric layer to make contact with the second nitride-based semiconductor layer. The first contact electrode has two opposite inner sidewalls facing each other and extends upward from the second nitride-based semiconductor layer. The passivation layer is disposed above the dielectric layer and covers the first contact electrode. The passivation layer extends downward and along the inner sidewalls of the contact electrode.

In accordance with one aspect of the present disclosure, a method for manufacturing a semiconductor device is provided. The method includes steps as follows. A first nitride-based semiconductor layer is formed. A second nitride-based semiconductor layer is formed on the first nitride-based semiconductor layer. A gate electrode is formed over the second nitride-based semiconductor layer. A dielectric layer is formed above the gate electrode and has at least one contact opening to expose the second nitride-based semiconductor layer. A contact electrode is formed above the dielectric layer and in the contact opening to make contact with the second nitride-based semiconductor layer. The contact electrode has at least one discontinuity region to expose the second nitride-based semiconductor layer.

By the above configuration, the semiconductor device adopts a design that the discontinuous contact electrode includes one or more enclosed discontinuities. The enclosed discontinuity can lead to a reduction in the area of the contact electrode, such that the thermal stress between the contact electrode and the nitride-based semiconductor layer can be alleviated. Thus, the probability of generating cracks can be reduced, and the electrical properties, the reliability, and the yield rate of the semiconductor device can be improved.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1A is a top view of a semiconductor device according to some embodiments of the present disclosure;

FIG. 1B is a vertical cross-sectional view across a line 1B-1B′ in FIG. 1A;

FIG. 1C is a vertical cross-sectional view across a line 1C-1C′ in FIG. 1A;

FIG. 2A and FIG. 2B show different stages of a method for manufacturing a nitride-based semiconductor device according to some embodiments of the present disclosure;

FIG. 3 is a top view of a semiconductor device according to some embodiments of the present disclosure;

FIG. 4 is a top view of a semiconductor device according to some embodiments of the present disclosure;

FIG. 5 is a vertical cross-sectional view of a semiconductor device according to some embodiments of the present disclosure; and

FIG. 6 is a vertical cross-sectional view of a semiconductor device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “on,” “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

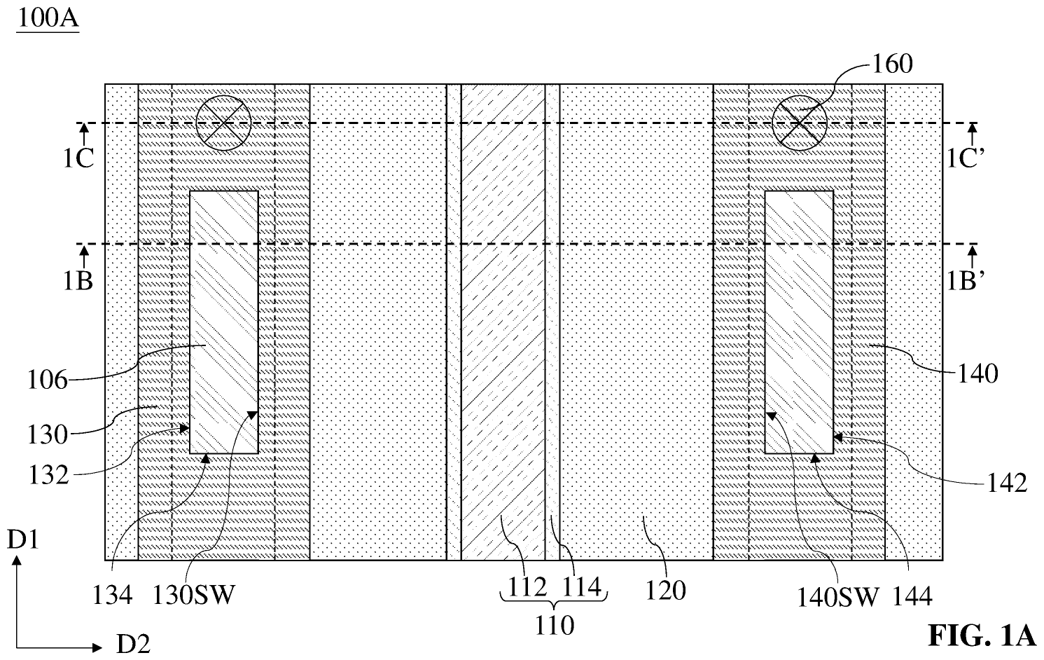

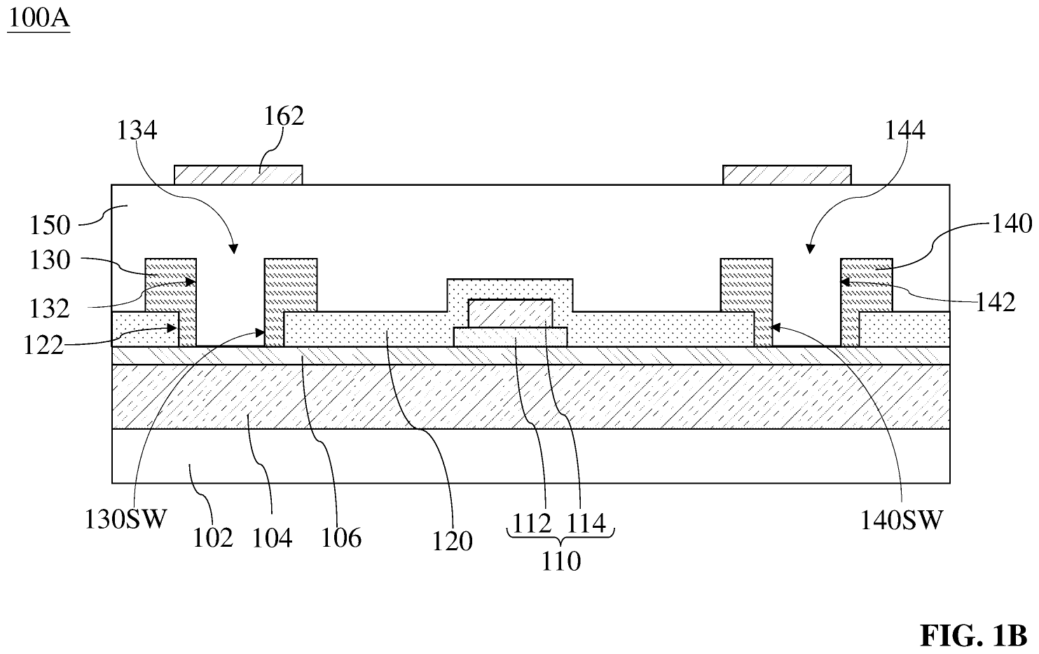

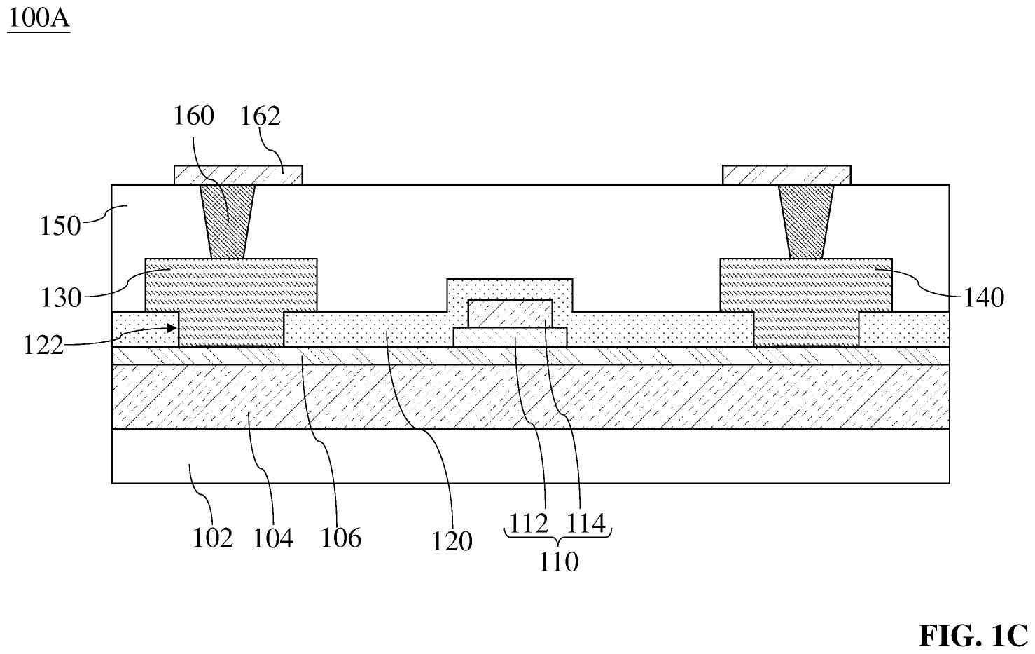

FIG. 1A is a top view of a semiconductor device 100A according to some embodiments of the present disclosure. FIG. 1B is a vertical cross-sectional view across a line 1B-1B′ in FIG. 1A. FIG. 1C is a vertical cross-sectional view across a line 1C-1C′ in FIG. 1A. In order to make the description clear, directions D1 and D2 are labeled in FIG. 1A, which are different than each other. In some embodiments, the directions D1 and D2 are orthogonal to each other. The semiconductor device 100A includes a substrate 102, nitride-based semiconductor layers 104 and 106, a gate structure 110, a dielectric layer 120, electrodes 130 and 140, a passivation layer 150, contact vias 160, and a patterned conductive layer 162. For clarity, the passivation layer 150 and the patterned conductive layer 162 are omitted in FIG. 1A.

The substrate 102 may be a semiconductor substrate. The exemplary materials of the substrate 102 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 102 can include, for example, but is not limited to, group III elements, group IV elements, group V elements, or combinations thereof (e.g., III-V compounds). In other embodiments, the substrate 102 can include, for example but is not limited to, one or more other features, such as a doped region, a buried layer, an epitaxial (epi) layer, or combinations thereof.

The nitride-based semiconductor layer 104 is disposed over the substrate 102. The nitride-based semiconductor layer 106 is disposed on the nitride-based semiconductor layer 104. The exemplary materials of the nitride-based semiconductor layer 104 can include, for example but are not limited to, nitrides or group III-V compounds, such as GaN, AlN, InN, InₓAl_{y}Ga_{(1-x-y)} N where x+y≤1, Al_{y}Ga_{(1-y)} N where y≤1. The exemplary materials of the nitride-based semiconductor layer 106 can include, for example but are not limited to, nitrides or group III-V compounds, such as GaN, AlN, InN, InₓAl_{y}Ga_{(1-x-y)} N where x+y≤1, Al_{y}Ga_{(1-y)} N where y≤1.

The exemplary materials of the nitride-based semiconductor layers 104 and 106 are selected such that the nitride-based semiconductor layer 106 has a bandgap (i.e., forbidden band width) greater than a bandgap of the nitride-based semiconductor layer 104, which causes electron affinities thereof different from each other and forms a heterojunction therebetween. For example, when the nitride-based semiconductor layer 104 is an undoped GaN layer having a bandgap of approximately 3.4 eV, the nitride-based semiconductor layer 106 can be selected as an AlGaN layer having bandgap of approximately 4.0 eV. As such, the nitride-based semiconductor layers 104 and 106 can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction. Accordingly, the semiconductor device 100A may include at least one GaN-based high-electron-mobility transistor (HEMT).

In some embodiments, the semiconductor device 100A may further include a buffer layer, a nucleation layer, or a combination thereof (not illustrated). The buffer layer can be disposed between the substrate 102 and the nitride-based semiconductor layer 104. The buffer layer can be configured to reduce lattice and thermal mismatches between the substrate 102 and the nitride-based semiconductor layer 104, thereby curing defects due to the mismatches/difference. The buffer layer may include a III-V compound. The III-V compound can include, for example but are not limited to, aluminum, gallium, indium, nitrogen, or combinations thereof. Accordingly, the exemplary materials of the buffer layer can further include, for example but are not limited to, GaN, AlN, AlGaN, InAlGaN, or combinations thereof. The nucleation layer may be formed between the substrate 102 and the buffer layer. The nucleation layer can be configured to provide a transition to accommodate a mismatch/difference between the substrate 102 and a III-nitride layer of the buffer layer. The exemplary material of the nucleation layer can include, for example but is not limited to AlN or any of its alloys.

The gate structure 110 is disposed on/above/over the nitride-based semiconductor layer 106. The gate structure 110 includes a doped nitride-based semiconductor layer 112 and a gate electrode 114. In the layout of the semiconductor device 100A, the doped nitride-based semiconductor layer 112 and the gate electrode 114 can extend along the direction D1. The doped nitride-based semiconductor layer 112 is disposed on the nitride-based semiconductor layer 106. The doped nitride-based semiconductor layer 112 is in contact with the nitride-based semiconductor layer 106. The doped nitride-based semiconductor layer 112 is disposed between the nitride-based semiconductor layer 106 and the gate electrode 114. The gate electrode 114 is disposed on the doped nitride-based semiconductor layer 112. The gate electrode 114 is in contact with the doped nitride-based semiconductor layer 112.

In the exemplary illustrations of FIGS. 1A, 1B, and 1C, a width of the doped nitride-based semiconductor layer 112 is greater than that of the gate electrode 114. In some embodiments, a width of the doped nitride-based semiconductor layer 112 can be substantially the same as a width of the gate electrode 114. In the exemplary illustrations of FIGS. 1B and 1C, the profiles of the doped nitride-based semiconductor layer 112 and the gate electrode 114 are the same. For example, the doped nitride-based semiconductor layer 112 and the gate electrode 114 are rectangular profiles in a vertical cross-section. In other embodiments, the profiles of the doped nitride-based semiconductor layer 112 and the gate electrode 114 can be different from each other. For example, the profile of the doped nitride-based semiconductor layer 112 can be a trapezoid profile in a vertical cross-section, and the profile of the gate electrode 114 can be a rectangular profile in a vertical cross-section.

In the exemplary illustration of FIGS. 1B and 1C, the semiconductor device 100A is an enhancement mode device, which is in a normally-off state when the gate electrode 114 is at approximately zero bias. Specifically, the doped nitride-based semiconductor layer 112 may create at least one p-n junction with the nitride-based semiconductor layer 106 to deplete the 2DEG region, such that at least one zone of the 2DEG region corresponding to a position below the corresponding the gate electrode 114 has different characteristics (e.g., different electron concentrations) than the rest of the 2DEG region and thus is blocked. Due to this mechanism, the semiconductor device 100A has a normally-off characteristic. In other words, when no voltage is applied to the gate electrode 114 or a voltage applied to the gate electrode 114 is less than a threshold voltage (i.e., a minimum voltage required to form an inversion layer below the gate electrode 114), the zone of the 2DEG region below the gate electrode 114 is kept blocked, and thus no current flows therethrough.

In some embodiments, the doped nitride-based semiconductor layer 112 can be omitted, such that the semiconductor device 100A is a depletion-mode device, which means the semiconductor device 100A in a normally-on state at zero gate-source voltage.

The doped nitride-based semiconductor layer 112 can be a p-type doped III-V semiconductor layer. The exemplary materials of the doped nitride-based semiconductor layer 112 can include, for example but are not limited to, p-doped group III-V nitride semiconductor materials, such as p-type GaN, p-type AlGaN, p-type InN, p-type AlInN, p-type InGaN, p-type AlInGaN, or combinations thereof. In some embodiments, the p-doped materials are achieved by using a p-type impurity, such as Be, Zn, Cd, and Mg. In some embodiments, the nitride-based semiconductor layer 104 includes undoped GaN and the nitride-based semiconductor layer 106 includes AlGaN, and the doped nitride-based semiconductor layer 112 is a p-type GaN layer which can bend the underlying band structure upwards and deplete the corresponding zone of the 2DEG region, so as to place the semiconductor device 100A into an off-state condition.

The exemplary materials of the gate electrode 114 may include metals or metal compounds. The gate electrode 114 may be formed as a single layer, or plural layers of the same or different compositions. The exemplary materials of the metals or metal compounds can include, for example but are not limited to, W, Au, Pd, Ti, Ta, Co, Ni, Pt, Mo, TiN, TaN, metal alloys or compounds thereof, or other metallic compounds.

The dielectric layer 120 is disposed on/over/above the nitride-based semiconductor layer 106 and the gate structure 110. The dielectric layer 120 includes a plurality of contact openings 122. The dielectric layer 120 can be conformal with the gate structure 110. The material of the dielectric layer 120 can include, for example but is not limited to, dielectric materials. The exemplary materials of the dielectric layer 120 can include, for example but are not limited to, SiNₓ, SiOₓ, Si₃N₄, SiON, SiC, SiBN, SiCBN, oxides, nitrides, plasma enhanced oxide (PEOX), or combinations thereof. In some embodiments, the dielectric layer 120 can be a multilayered structure, such as a composite dielectric layer of Al₂O₃/SiN, Al₂O₃/SiO₂, AlN/SiN, AlN/SiO₂, or combinations thereof.

Each of the electrodes 130 and 140 can serve as a source electrode or a drain electrode, depending on the device design. In some embodiments, the electrode 130 can serve as a source electrode. In some embodiments, the electrode 130 can serve as a drain electrode. In some embodiments, the electrode 140 can serve as a source electrode. In some embodiments, the electrode 140 can serve as a drain electrode. The role of the electrodes 130 and 140 depends on the device design.

The electrodes 130 and 140 are disposed on/above/over the nitride-based semiconductor layer 106. The electrodes 130 and 140 can extend through the contact openings 122 of the dielectric layer 120 to make contact with the nitride-based semiconductor layer 106. The electrodes 130 and 140 can be electrically coupled with the 2DEG region through the contact with the nitride-based semiconductor layer 106, so the electrodes 130 and 140 can be called contact electrodes as well. The electrodes 130 and 140 can penetrate the dielectric layer 120. In the layout of the semiconductor device 100A, the electrodes 130 and 140 can extend along the direction D1. In the layout of the semiconductor device 100A, the gate electrode 114 and the electrodes 130 and 140 can be arranged along the direction D2.

The doped nitride-based semiconductor layer 112 and the gate electrode 114 are located between the electrodes 130 and 140. That is, the electrodes 130 and 140 can be located at two opposite sides of the gate electrode 114, respectively. In some embodiments, other configurations may be used, particularly when plural source, drain, or gate electrodes are employed in the device. In the exemplary illustration of FIGS. 1B and 1C, the electrodes 130 and 140 are symmetrical about the gate electrode 114. In other embodiments, the electrodes 130 and 140 are asymmetrical about the gate electrode 114. For example, the electrode 130 can be closer to the gate electrode 114 than the electrode 140.

In some embodiments, the electrodes 130 and 140 can include, for example but are not limited to, metals, alloys, doped semiconductor materials (such as doped crystalline silicon), compounds such as silicides and nitrides, other conductor materials, or combinations thereof. The exemplary materials of the electrodes 130 and 140 can include, for example but are not limited to, Ti, AlSi, TiN, or combinations thereof. The electrodes 130 and 140 may be a single layer, or plural layers of the same or different composition. In some embodiments, the electrodes 130 and 140 form ohmic contacts with the nitride-based semiconductor layer 106; therefore, the electrodes 130 and 140 can be served as the contact electrodes. The ohmic contacts can be achieved by applying Ti, Al, or other suitable materials to the electrodes 130 and 140. In some embodiments, each of the electrodes 130 and 140 is formed by at least one conformal layer and a conductive filling. The conformal layer can wrap the conductive filling. The exemplary materials of the conformal layer, for example but are not limited to, Ti, Ta, TiN, Al, Au, AlSi, Ni, Pt, or combinations thereof. The exemplary materials of the conductive filling can include, for example but are not limited to, AlSi, AlCu, or combinations thereof.

With respect to the formation of the electrodes 130 and 140, a blanket conductive layer can be formed and then a patterning process is performed to form the separated electrodes 130 and 140. The separated electrodes 130 and 140 can be formed with at least one aperture/opening created by the patterning process. The at least one aperture/opening can be employed to alleviate stress in the separated electrodes 130 and 140.

To further illustrate the concept, it should be noted that a material difference between different element layers may lead to thermal stress. With respect to the thermal stress issue, as considered a semiconductor device including source and drain electrodes, the source and drain electrodes may have materials differing from those of a layer formed under or above the source and drain electrodes, and therefore the thermal stress may accumulate in the source and drain electrodes. For example, the stress accumulation tends to occur at the corner portions of the source and drain electrodes. Once the source and drain electrodes have no aperture/opening therein, the thermal stress accumulation would increase gradually. When the thermal stress accumulation reaches a certain extent, cracks would be generated in the layer due to the thermal stress from the source and drain electrodes, thereby deteriorating the electrical properties, the reliability, and the yield rate of the semiconductor device.

For the source and drain electrodes having no aperture/opening therein, they can be called “continuous electrode.” Herein, the phrase “continuous electrode” means that an electrode has no inner boundary/border between two opposite edges thereof in any vertical cross-sectional view of the same electrode. Explained in another way, between the two opposite edges of the electrode, no layer penetrates the electrode.

Referring to FIGS. 1A and 1B, with respect to the thermal stress issue, the electrodes 130 and 140 can be designed as a discontinuous electrode at least for the purpose of avoiding accumulation of thermal stress. Such a configuration can alleviate the afore-mentioned negative effects due to thermal stress. Herein, the phrase “discontinuous electrode” means that, in at least one vertical cross-sectional view of the electrode, the electrode has at least one inner boundary/border between the two opposite edges thereof. Explained in another way, between the two opposite edges of each of the discontinuous electrode, at least one layer would penetrate thereof. For example, the passivation layer 150 can penetrate the electrodes 130 and 140 to make contact with the nitride-semiconductor layer 106 and form interfaces with the inner boundaries/borders of the electrodes 130 and 140.

To be more specific, referring to FIGS. 1A and 1B, the electrode 130 includes, for example, one enclosed discontinuity 134 in a discontinuity region 132 thereof. The discontinuity region 132 can be referred to as an aperture/opening of the electrode 130. The electrode 130 has two or more inner sidewalls 130SW. The inner sidewalls 130SW face each other in the discontinuity region 132. The inner sidewalls 130SW can extend upward from the nitride-based semiconductor layer 106.

The inner sidewalls 130SW define an inner border/boundary of the electrode 130. The enclosed discontinuity 134 of the electrode 130 has a width less than a length thereof. The length of the discontinuity region 132 along the direction D1 is greater than the length of the discontinuity region 132 along the direction D2. The inner boundary of the discontinuity region 132 surrounding the enclosed discontinuity 134 can have a plurality of straight edges. For example, the inner boundary of the discontinuity region 132 can be in a shape of quadrilateral, such as rectangle, square, rhombus, or trapezoid. In other embodiments, the inner boundary of the discontinuity region 132 surrounding the enclosed discontinuity 134 can be designed as being other shapes, such as triangle, pentagon, hexagon, or polygons.

It should be noted that the configuration of the electrode 130 can be applied to that of the electrode 140, such that the electrode 140 includes one enclosed discontinuity 144 in a discontinuity region 142 thereof. In some embodiment, in order to comply with other electrical requirements, one of the electrodes can be modified to become solid. That is to say, one of the electrodes can be a discontinuous electrode and the another one of electrodes can be a continuous electrode.

As compared with a continuous electrode, the area of the electrode 130 can be reduced by creating the enclosed discontinuity 134 in the discontinuity region 132. As such, the accumulation of the thermal stress in the electrode 130 can be lowered, thereby improving the reliability thereof. Moreover, the cracks induced by the thermal stress can be reduced, and thus the electrical properties of the semiconductor device 100A can be improved. Since the electrode 140 can have the configuration identical with or similar to the electrode 130 as afore-described, the electrode 140 can have the technical effect as the electrode 130.

The passivation layer 150 is disposed on/over/above the dielectric layer 120, and the electrodes 130 and 140. The passivation layer 150 penetrates the electrodes 130 and 140 in the discontinuity regions 132 and 142 to make contact with the nitride-based semiconductor layer 106. That is to say, the passivation layer 150 can have portions penetrating the electrodes 130 and 140. More specifically, the portions of the passivation layer 150 extend into/fills with the discontinuity regions 132 and 142 (e.g., the aperture/opening of the electrodes 130 and 140) to form interfaces with the electrode 130 and with the electrode 140. The portions of the passivation layer 150 can be in contact with the nitride-based semiconductor layer 106 through the discontinuity regions 132 and 142.

The passivation layer 150 is in contact with the inner sidewalls 130SW and 140SW. The passivation layer 150 can extend downward and along the inner sidewalls 130SW and 140SW. The inner sidewalls 130SW and 140SW of the electrodes 130 and 140 are entirely covered by portions of the passivation layer 150. The inner sidewall 130SW of the electrode 130 can enclose/surround the portion of the passivation layer 150 within the enclosed discontinuity 132. The inner sidewall 140SW of the electrodes 140 can enclose/surround the portion of the passivation layer 150 within the enclosed discontinuity 142. Therefore, each of the electrodes 130 and 140 can accommodate a material different than itself in the discontinuity region 132 or 144. For example, a dielectric material of the passivation layer 150 can be accommodated in the conductive materials of the electrodes 130 and.

As compared with a continuous electrode, theses portions of the passivation layer 150 are enclosed by the discontinuity regions 132 and 142, which means that the portions of the passivation layer 150 are embedded in the electrodes 130 and 140. As such, the contact area between the passivation layer 150 and the electrodes 130 and 140 can be enhanced, thereby avoiding the passivation layer 150 peeling off from the electrode 130 and 140.

In some embodiments, the passivation layer 150 can serve as a planarization layer which has a level top surface to support other layers/elements. In some embodiments, the passivation layer 150 can be formed as a thicker layer, and a planarization process, such as chemical mechanical polish (CMP) process, is performed on the passivation layer 150 to remove the excess portions, thereby forming a level top surface.

The contact vias 160 are disposed within the passivation layer 150. The contact vias 160 can penetrate the passivation layer 150. The contact vias 160 can extend longitudinally to connect to the electrodes 130 and 140, respectively. Each of the contact vias 160 is adjacent with the corresponding discontinuity region 132 or 142. The upper surfaces of the contact vias 160 are free from coverage of the passivation layer 150. The exemplary materials of the contact vias 160 can include, for example but are not limited to, conductive materials, such as metals or alloys.

The patterned conductive layer 162 is disposed on/over/above the passivation layer 150 and the contact vias 160. The patterned conductive layer 162 is in contact with the contact vias 160. The patterned conductive layer 162 vertically overlaps with the enclosed discontinuity 134 of the electrode 130 in the discontinuity region 132 and the enclosed discontinuity 144 of the electrode 140 in the discontinuity region 142. The patterned conductive layer 162 may have metal lines, pads, traces, or combinations thereof, such that the patterned conductive layer 162 can form at least one circuit. Hence, the patterned conductive layer 162 can be served as a patterned circuit layer. The exemplary materials of the patterned conductive layer 162 can include, for example but are not limited to, conductive materials. The patterned conductive layer 162 may include a single film or multilayered film having Ag, Al, Cu, Mo, Ni, Ti, alloys thereof, oxides thereof, nitrides thereof, or combinations thereof.

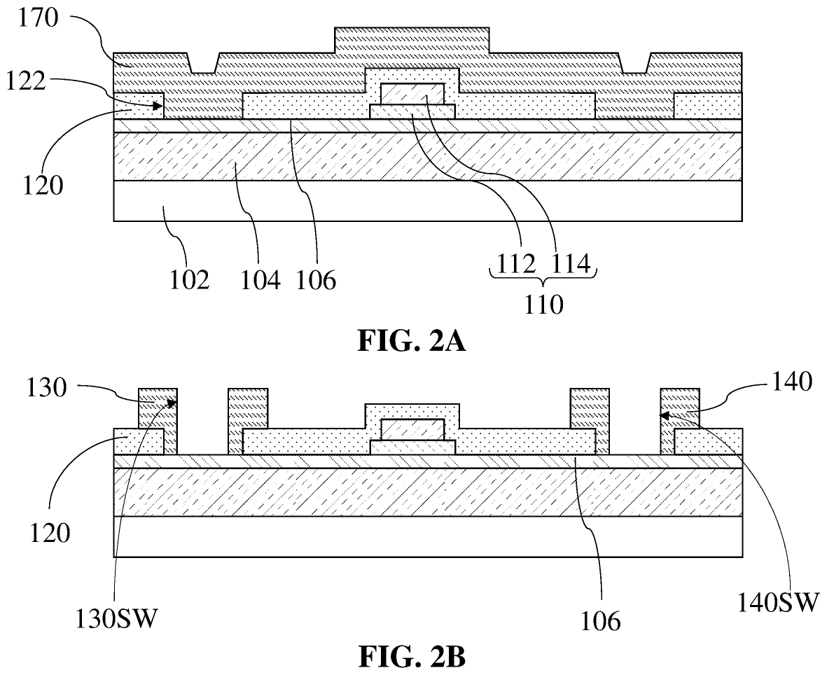

Different stages of a method for manufacturing the semiconductor device 100A are shown in FIG. 2A and FIG. 2B, as described below. In the following, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

Referring to FIG. 2A, a nitride-based semiconductor layer 104 is formed on a substrate 102 by using deposition techniques. A nitride-based semiconductor layer 106 can be formed on the nitride-based semiconductor layer 104 by using deposition techniques. A doped nitride-based semiconductor 112 and a gate electrode 114 can be formed over a nitride-based semiconductor layer 106 by using deposition techniques. A dielectric layer 120 is formed to have at least one contact opening 122 to expose the nitride-based semiconductor layer 106. A blanket conductive layer 170 is formed above the dielectric layer 120. The blanket conductive layer 170 has portions fully filled/introduced/deposited in the contact opening 122, so that the blanket conductive layer 170 can make contact with the nitride-based semiconductor layer 106 through the contact openings 122. The formation of the doped nitride-based semiconductor layer 112, the gate electrode 114, and the dielectric layer 120 includes a patterning process. In some embodiments, the deposition techniques can be performed for forming a blanket layer, and the patterning process can be performed for removing excess portions thereof. In some embodiments, the patterning process can include photolithography, exposure and development, etching, other suitable processes, or combinations thereof.

Referring to FIG. 2B, a patterning process is performed on the blanket conductive layer 170 to form the electrodes 130 and 140 having the discontinuity regions 134 and 142 respectively. The discontinuity region 132 has two opposite inner sidewalls 130SW facing each other in the discontinuity region 132. The discontinuity region 132 exposes nitride-based semiconductor layer 106. The discontinuity region 142 has two opposite inner sidewalls 140SW facing each other in the discontinuity region 142. The discontinuity region 142 exposes nitride-based semiconductor layer 106.

The inner sidewalls 130SW and 140SW are formed to be perpendicular to a top surface of the nitride-based semiconductor layer 106. The formed electrodes 130 and 140 are located above the nitride-based semiconductor layer 106 and in the contact openings 122 to make contact with the nitride-based semiconductor layer 106. Thereafter, the passivation layer 150, the contact vias 160, and the patterned conductive layer 162 can be formed, obtaining the configuration of the semiconductor device 100A as shown in FIGS. 1A, 1B and 1C.

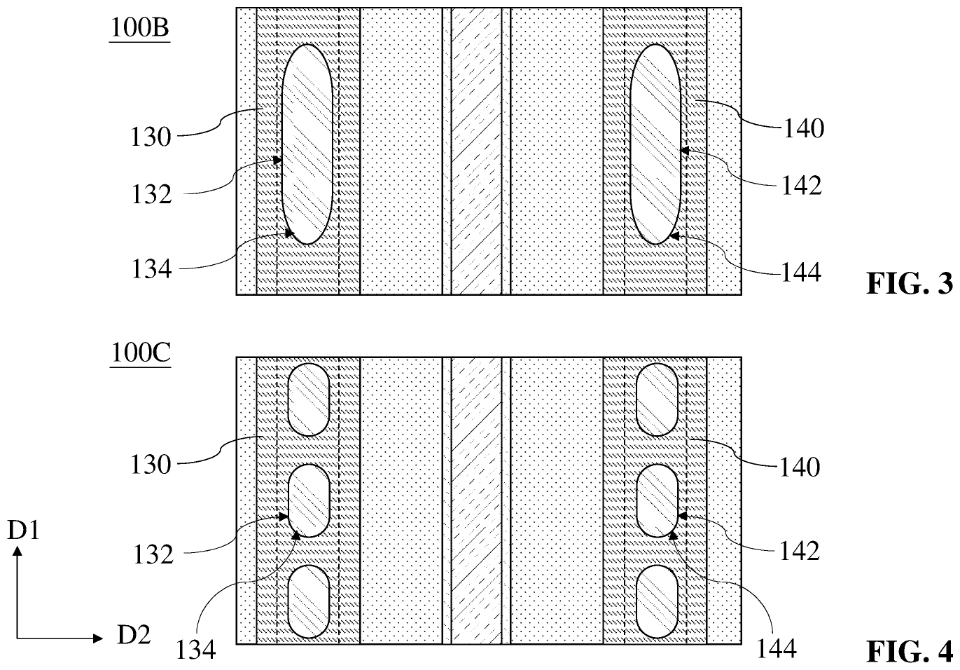

FIG. 3 is a top view of a semiconductor device 100B according to some embodiments of the present disclosure. In the exemplary illustration of FIG. 3, the electrode 130 can have a curved border/inner boundary in the discontinuity region 132. Specifically, the electrode 130 has an inner boundary surrounding one enclosed discontinuity 134 in a shape of ellipse. The configuration of the electrode 130 can be applied to that of the electrode 140, such that the electrode 140 has an inner boundary surrounding one enclosed discontinuity 144 in a shape of ellipse. In some embodiments, the electrode 130 or 140 has an inner boundary surrounding one enclosed discontinuity 134 or 144 in a shape of circle. The design of the curved border/inner boundary can achieve a desirable stress distribution in the semiconductor device 100B.

FIG. 4 is a top view of a semiconductor device 100C according to some embodiments of the present disclosure. In the exemplary illustration of FIG. 4, the electrode 130 can have a plurality of separated and enclosed discontinuities 134 in the discontinuity regions 132 thereof. Accordingly, a plurality of portions of the passivation layer 150 (see FIG. 1B) are within these enclosed discontinuities 134. These enclosed portions of the passivation layer 150 are enclosed by the electrode 130. That is to say, the enclosed portions of the passivation layer 150 are separated from each other by the discontinuity regions 132 of the electrode 130. The enclosed portions of the passivation layer 150 are arranged along the direction D1. The extending direction of the electrodes 130 and 140 and the gate electrode 114 can be substantially the same as the arrangement direction of the enclosed portions of the passivation layer 150.

The discontinuity regions 132 of the electrode 130 are in a shape of ellipse. The configuration of the electrode 130 can be applied to that of the electrode 140, such that the electrode 140 can have a plurality of separated and enclosed discontinuity regions 142 which are in a shape of ellipse. Similarly, the curved inner borders/inner boundaries of the discontinuity regions 132 and 142 are advantageous to the distribution of the accumulation of the stress. In some embodiments, in order to meet other electrical requirements, the shapes of the discontinuity regions 132 can be rectangle, circle, ellipse, or combinations thereof, and the disclosure is not limited thereto.

During the manufacturing processes of the semiconductor devices 100B and 100C, the blanket conductive layer 170 can be patterned to form the electrodes 130 and 140 having the discontinuity regions 132 and 142. The discontinuity regions 132 and 142 of the electrode 130 and 140) can be formed to have a curved border. In detail, the discontinuity regions 132 and 142 can be patterned by a dry etching process, and the numbers and the shapes of the discontinuity regions 132 and 142 can be determined by the patterns of the mask which is applied during the etching process. As such, the discontinuous electrode design of the present disclosure is flexible, being available to satisfy different device requirements.

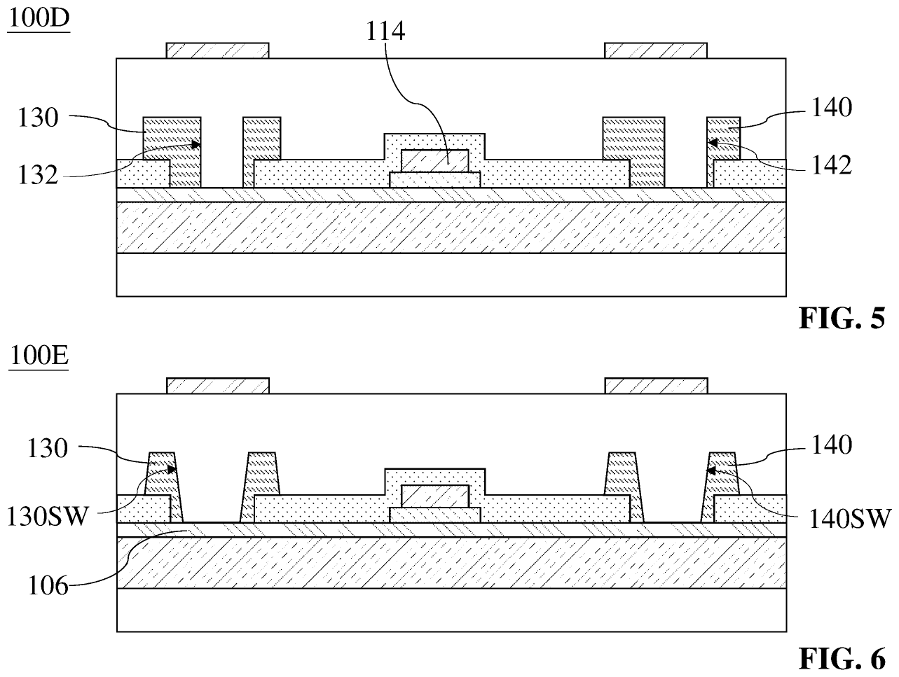

FIG. 5 is a vertical cross-sectional view of a semiconductor device 100D according to some embodiments of the present disclosure. In some operations, a high voltage is applied to the drain electrode (e.g., the electrode 140), be higher than the source electrode (e.g., the electrode 130). As such, the electric field intensity would not uniformly/evenly distribute within the afore-mentioned inter-electrode regions. This phenomenon would exacerbate the electrical properties of the semiconductor device.

In the exemplary illustration of FIG. 5, the electrodes 130 and 140 can be provided with an asymmetric design. Specifically, the electrodes 130 and 140 are asymmetrical about the gate electrode 114. The asymmetric design can include asymmetrical profile. For example, the electrodes 130 and 140 have different profile at the discontinuity regions 132 and 142 thereof. A distance from the discontinuity region 132 to the gate electrode 114 can be less than a distance from the discontinuity region 142 to the gate electrode 114. In other words, the discontinuity region 132 is closer to the gate electrode 114 than the discontinuity region 142. The asymmetric design can make the electric field distribution more uniform in the semiconductor device 100D, thereby improving the electrical properties thereof.

During the manufacturing process of the semiconductor devices 100D, the discontinuity regions 132 and 142 can be patterned by a dry etching process, and the relative position of the discontinuity region 132 (or 142) with respect to the gate electrode 114 can be determined by positions of the patterns of the mask which applied during the etching process.

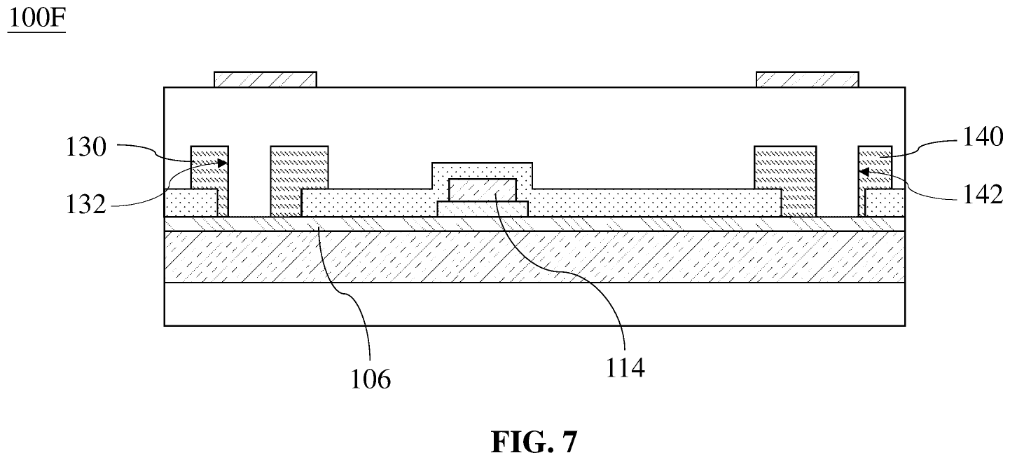

FIG. 6 is a vertical cross-sectional view of a semiconductor device 100E according to some embodiments of the present disclosure. In the exemplary illustration of FIG. 6, the inner sidewalls 130SW and 140SW of the electrodes 130 and 140 are oblique with respect to the nitride-based semiconductor layer 106, such that the portions of the passivation layer 150 can extend obliquely downward along the inner sidewalls 130SW and 140SW. Such a configuration can further increase the contact area between the electrodes 130 and 140 and the passivation layer 150. Moreover, the force from the passivation layer 150 (the force component from the passivation 150) can have more vertical components applying to the electrodes 130 and 140. Therefore, it can avoid a peeling issue. Hence, the reliability of the semiconductor device 100E can be further promoted.

During the manufacturing process of the semiconductor device 100E, the blanket conductive layer 170 can be patterned to form the electrodes 130 and 140 having the discontinuity regions 132 and 142 with oblique inner sidewalls 130SW and 140SW. The inclination of the oblique inner sidewalls 130SW and 140SW can be controlled by tuning at least one parameter, such as time, temperature, pressure, or etchant during the stage of patterning the conductive layer 170.

FIG. 7 is a vertical cross-sectional view of a semiconductor device 100F according to some embodiments of the present disclosure. In the exemplary illustration of FIG. 7, the electrodes 130 and 140 are asymmetrical about the gate electrode 114. The electrode 130 is closer to the gate electrode 114 than the electrode 140.

With respect to the electrode 130, the discontinuity region 132 is created near a left side of the electrode 130. With respect to the electrode 140, the discontinuity region 142 is created near a right side of the electrode 140. Such a configuration can be employed to make good contact with the nitride-based semiconductor layer because the thicker portions of the electrodes 130 and 140 connect to the drift region.

Based on the above description, in the embodiments of the present disclosure, since at least one of the electrodes can be provided with at least one or more discontinuities in a discontinuity region which leads to an area reduction, such that the negative influence caused by the stress can be mitigated. The cracks generated by the thermal stress can be reduced. Accordingly, the semiconductor device of the present disclosure can have good electrical properties, reliability and yield rate. Moreover, since at least one portion of the passivation layer can extend downward and along the inner sidewalls of at least one of the electrodes, the contact area between the passivation layer and the electrode can be increased, thereby increasing the bonding force therebetween and avoiding a peeling issue. Consequently, the semiconductor device of the present disclosure can have good reliability and yield rate.

The embodiments were chosen and described in order to best explain the principles of the disclosure and its practical application, thereby enabling others skilled in the art to understand the disclosure for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 within 30 within 20 within 10 or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A semiconductor device, comprising:
a first nitride-based semiconductor layer;
a second nitride-based semiconductor layer disposed on the first nitride-based semiconductor layer and having a bandgap greater than a bandgap of the first nitride-based semiconductor layer;
a gate electrode disposed above the second nitride-based semiconductor layer;
a dielectric layer disposed above the second nitride-based semiconductor layer and covering the gate electrode;
a first contact electrode disposed above the second nitride-based semiconductor layer and penetrating the dielectric layer to make contact with the second nitride-based semiconductor layer, wherein the first contact electrode includes one or more enclosed discontinuities in a first discontinuity region thereof; and
a passivation layer disposed above the dielectric layer and covering the first contact electrode, wherein the passivation layer penetrates the first contact electrode in the first discontinuity region to make contact with the second nitride-based semiconductor layer.

2. The semiconductor device of claim 1, wherein the first contact electrode encloses at least one portion of the passivation layer within its one or more enclosed discontinuities.

3. The semiconductor device of claim 1, wherein the first contact electrode has two inner sidewalls facing each other in the first discontinuity region.

4. The semiconductor device of claim 3, wherein the passivation layer is in contact with the inner sidewalls of the first discontinuity region of the first contact electrode.

5. The semiconductor device of claim 3, wherein the inner sidewalls of the first contact electrode are oblique with respect to the second nitride-based semiconductor layer.

6. The semiconductor device of claim 1, further comprising:
a contact via extending to connect the first contact electrode and adjacent with the first discontinuity region of the first contact electrode.

7. The semiconductor device of claim 1, wherein the first contact electrode has an inner boundary surrounding the one or more enclosed discontinuities in a shape of rectangle, circle, ellipse, or combinations thereof.

8. The semiconductor device of claim 1, wherein the first contact electrode has a curved inner boundary in the discontinuity region.

9. The semiconductor device of claim 1, wherein the first contact electrode includes a plurality of the enclosed discontinuities in the first discontinuity regions thereof, such that a plurality of portions of the passivation layer are within the enclosed discontinuities.

10. The semiconductor device of claim 9, wherein the portions of the passivation layer are separated from each other by the discontinuity regions of the first contact electrode.

11. The semiconductor device of claim 9, wherein the gate electrode and the first contact electrode extend along a direction, and the portions of the passivation layer are arranged along the direction.

12. The semiconductor device of claim 1 further comprising:
a second contact electrode disposed above the second nitride-based semiconductor layer and penetrating the dielectric layer to make contact with the second nitride-based semiconductor layer, wherein the gate electrode is located between the first and second contact electrodes, and the second contact electrode includes one or more enclosed discontinuities in a second discontinuity region thereof.

13. The semiconductor device of claim 12, wherein the first and second contact electrodes are asymmetrical about the gate electrode.

14. The semiconductor device of claim 1, wherein the enclosed discontinuity of the first contact electrode has a width less than a length thereof.

15. The semiconductor device of claim 1, further comprising:
a conductive layer disposed above the passivation layer and vertically overlapping with the one or more enclosed discontinuities of the first contact electrode in the first discontinuity region.

16. A method for manufacturing a semiconductor device, comprising:
forming a first nitride-based semiconductor layer;
forming a second nitride-based semiconductor layer on the first nitride-based semiconductor layer;
forming a gate electrode over the second nitride-based semiconductor layer;
forming a dielectric layer above the gate electrode and having at least one contact opening to expose the second nitride-based semiconductor layer; and
forming a contact electrode above the dielectric layer and in the contact opening to make contact with the second nitride-based semiconductor layer, wherein the contact electrode has at least one discontinuity region to expose the second nitride-based semiconductor layer.

17. The method of claim 16, further comprising:
forming a blanket conductive layer above the dielectric layer and fully fill in the contact opening; and
patterning the blanket conductive layer to form the contact electrode having the discontinuity region.

18. The method of claim 17, wherein patterning the blanket conductive layer is performed such that contact electrode has two opposite inner sidewalls facing each other.

19. The method of claim 17, wherein patterning the blanket conductive layer is performed such that contact electrode has two opposite inner sidewalls oblique with respect to the second nitride-based semiconductor layer.

20. The method of claim 17, wherein patterning the blanket conductive layer is performed such that the discontinuity region has a curved border.

21-25. (canceled)
